(19) United States
(12) Patent Application Publication
(10) Pub. No.: US 2014/0307242 A1
(43) Pub. Date: Oct. 16, 2014

(54) METHOD AND APPARATUS FOR PRINTING PERIODIC PATTERNS USING MULTIPLE LASERS

(71) Applicants: Harun Solak, Brugg (CH); Francis Clube, Hausen (CH); Christian Dais, Brugg (CH)

(72) Inventors: Harun Solak, Brugg (CH); Francis Clube, Hausen (CH); Christian Dais, Brugg (CH)

(73) Assignee: EULITHA A.G., Villigen PSI (CH)

(21) Appl. No.: 14/123,330

(22) PCT Filed: Jun. 1, 2012
(86) PCT No.: PCT/IB2012/052778

§ 371 Date: Feb. 4, 2014

Related U.S. Application Data
(60) Provisional application No. 61/492,039, filed on Jun. 1, 2011.
(60) Provisional application No. 61/531,642, filed on Sep. 7, 2011.

(51) Int. Cl. G03F 7/20

(52) U.S. Cl. CPC G03F 7/70075
USPC 355/67; 355/77

(57) ABSTRACT

A method for printing a periodic pattern of features into a photosensitive layer includes providing a mask bearing a mask pattern, providing a substrate bearing the layer, arranging the substrate parallel to the mask, providing a number of lasers having a plurality of peak wavelengths, forming from the light a beam for illuminating the mask with a spectral distribution of exposure dose and a degree of collimation, illuminating the mask with the beam such that the light of each wavelength transmitted by the mask pattern forms a range of transversal intensity distributions between Talbot planes and exposes the photosensitive layer to an image component. The separation and the spectral distribution are arranged so that the superposition of the components is equivalent to an average of the range of transversal intensity distributions formed by light of one wavelength and the collimation is arranged so that the features are resolved.

This invention relates generally to the field of photolithography as employed for the fabrication of micro- and nano-structures, and relates particularly to the field of photolithography based on the Talbot effect, or self-imaging.

Lithographic fabrication enables the formation of micro- and nano-patterns on surfaces. Photolithographic techniques achieve this by exposing a photosensitive surface to a light-field with an intensity distribution corresponding to the desired pattern. The photosensitive surface is usually a thin layer of a sensitive material, such as photoresist, which is coated either directly on a substrate surface or indirectly over intermediate layers of other materials. Chemical or physical changes that occur in the photosensitive layer as a result of the exposure are used in subsequent processes to obtain a desired pattern in the material of the substrate or in an intermediate layer of another material. In the most commonly used photolithographic technique an image of a pattern defined in a mask is projected onto the substrate surface using an optical system. The masks generally employed in such conventional systems are amplitude masks in which the pattern features are defined as open areas in a layer of an opaque material, usually chrome, on a transparent substrate. Phase-shift masks (PSMs) are alternatively used in which the pattern features are defined using a certain thickness of a material or a depth of recess into a material, so that the light propagating through those features is shifted in phase with respect to other propagating light, which then mutually interfere in the image plane to form the desired pattern. In the case of PSMs employed in projection, contact, proximity or conventional Talbot lithography, the mask is designed by considering the interference between all the diffraction orders transmitted by the mask. In the case of a one-dimensional pattern, a PSM can reduce the minimum printable period by a factor of two with respect to an amplitude mask. This is mainly achieved by suppressing the 0th-order diffracted beam, thereby eliminating the intensity modulation produced by its interference with the 1st-order diffracted beams.

For many applications patterns are required that comprise a unit cell of pattern features that repeat in one or two dimensions, that is, periodic patterns. A specialized photolithographic technique for transferring such patterns from masks onto substrates is based on the Talbot effect. When a periodic pattern defined in a mask is illuminated with a collimated beam of monochromatic light, diffraction orders in the transmitted light-field reconstruct “self-images” of the pattern at regular distances from the mask in so-called Talbot planes. The separation of these self-images, S, which is known as the Talbot distance, depends on the illumination wavelength, λ, and period of the pattern, p, according to:

$$S \approx \frac{{kp}^{2}}{λ} \qquad equ . ( 1 )$$

where k is a constant.

For a one-dimensional periodic pattern of lines and spaces, k=2, whereas for two-dimensional periodic patterns, the value of k depends on the array symmetry of the pattern. Although this formula has good accuracy when p>>λ (i.e. when the angle of the first diffracted order is small), it approximates less well as the magnitude of p approaches λ. Locating a photo resist-coated substrate at one of the self-image planes results in the mask pattern being printed into the photo resist (see, for example, C. Zanke, et al., “Large area patterning for photonic crystals via coherent diffraction lithography”, J. Vac. Sci. Technol. B 22, 3352 (2004)). Furthermore, at intermediate distances between the self-image planes, Talbot sub-images are formed that have higher spatial frequencies than the pattern in the mask, which may be printed by placing a photo resist-coated substrate at one of these sub-image planes. The printed results achieved using these techniques are improved when the duty cycle of the mask pattern (i.e. the dimension of the features as a fraction of the feature period) is selected to produce a high contrast of intensity variation in the Talbot or sub-image plane (see U.S. Pat. No. 4,360,586). It is also known in the prior art that the contrast of the Talbot images can be further enhanced by fabricating the periodic patterns in the mask using phase shifting materials. Photolithography using Talbot imaging is especially advantageous for printing high-resolution periodic patterns in view of the cost of conventional, projection-type photolithographic systems for printing high-resolution patterns.

A major shortcoming of the Talbot technique, however, is the sensitivity of the intensity distributions of the self-images and sub-images to the distance from the mask, that is, they have a very narrow depth of field. This means that the substrate needs to be positioned very accurately with respect to the mask in order to correctly print the pattern. This becomes increasingly more difficult as the grating period is reduced because the depths of field of the self-images and sub-images are proportional to the square of the pattern period. Furthermore, if the pattern needs to be printed onto a substrate surface that is not very flat, onto a surface that already has a high-relief micro-pattern on its surface, or into a thick layer of photoresist, then it may be impossible to achieve the desired result.

Achromatic Talbot lithography (ATL) has recently been introduced as a new method for printing high-resolution periodic patterns in a cost effective way (see H. H. Solak, et al., “Achromatic Spatial Frequency Multiplication: A Method for Production of Nanometer-Scale Periodic Structures”, J. Vac. Sci. Technol., 23, pp. 2705-2710 (2005), and U.S. Pat. Appl. no. 2008/0186579). It offers two significant advantages for lithographic applications: firstly, it overcomes the depth-of-field problem encountered using the classical Talbot method; and, secondly, for many pattern types it performs a spatial-frequency multiplication, that is, it increases the resolution of the printed features with respect to that of the pattern in the mask. In ATL the mask is illuminated with a collimated beam from a light source with a broad spectral bandwidth, and beyond a certain distance from the mask the transmitted light-field forms a so-called stationary image whose intensity distribution is substantially invariant to further increase in distance. In the case of a one-dimensional pattern of lines and spaces (i.e. a linear grating), the minimum distance, dₘᵢₙ, from the mask at which this occurs is related to the period, p, of the pattern in the mask and to the full width at half maximum, Δλ, of the beam's spectral profile by:

$${d}_{min} \approx \frac{2 {p}^{2}}{Δλ} \qquad equ . ( 2 )$$

Beyond this distance, the Talbot image planes for the different wavelengths are distributed in a continuous manner with increasing distance from the mask, which gives rise to the stationary image. Thus, by placing a photoresist-coated substrate in this region exposes the substrate to the entire range of transverse intensity distributions formed between successive Talbot planes for a particular wavelength. The pattern printed onto the substrate is therefore an average, or integration, of this range of transversal intensity distributions, which is substantially insensitive to longitudinal displacement of the substrate with respect to the mask. The technique therefore enables a much larger depth of field than with standard Talbot imaging, and a much larger depth of field than with conventional projection, proximity or contact printing.

The intensity distribution in an ATL image from a particular mask pattern may be determined using modelling software that simulates the propagation of electromagnetic waves through and after the mask. Such simulation tools may be used to optimize the design of the pattern in the mask for obtaining a particular printed pattern at the substrate surface.

The ATL method has been developed primarily to print periodic patterns that comprise a unit cell that repeats with a constant period in at least one direction. The technique may, however, also be successfully applied to patterns whose period spatially varies in a sufficiently “slow”, gradual way across the mask such that the diffraction orders that form a particular part of the stationary image are generated by a part of the mask in which the period is substantially constant. Such patterns may be described as being quasi-periodic.

A drawback of ATL is that it requires a light source with a significant spectral bandwidth in order that the separation required between the mask and substrate is not disadvantageously large. The angular divergence of the different diffracted orders propagating from the mask produces spatial offsets between the different orders at the substrate surface resulting in imperfect image reconstruction at the pattern edges, which becomes worse with increasing separation. Fresnel diffraction at the edges of the diffracted orders also degrades the edges of the printed pattern, and this likewise gets worse with increasing separation. For these reasons laser sources, which have relatively small spectral bandwidth, are in most cases unsuitable for ATL.

A difficulty with applying non-laser sources, such as arc lamps or light emitting diodes, to ATL is producing an exposure beam of the required dimensions that has the combination of high power for ensuring high throughput in a production process and good collimation for imaging high-resolution features. The collimation of beams from such sources may be improved to the required level by spatial filtering but this generally results in an unacceptable loss of the beam power.

The advantages of the ATL technique may be obtained using a different but related technique that is disclosed in U.S. Pat. Appl. no. 2008/0186579. In this scheme, the periodic pattern in the mask is illuminated by a collimated beam of monochromatic light and during exposure the distance of the substrate from the mask is varied over a range corresponding to an integer multiple of the separation between successive Talbot image planes in order that an average of the intensity distributions between Talbot planes is printed on the substrate. The smallest displacement that may be employed is therefore equal to the separation of successive Talbot planes (when integer=1). With this displacement during exposure, the pattern printed on the substrate is substantially the same as that printed using the ATL technique. It is disclosed that the displacement may be performed either continuously or in a discrete way by exposing the substrate at multiple discrete positions over the range. The general technique may be referred to as displacement Talbot lithography (DTL)

The average intensity distributions generated at the substrate using the ATL and DTL techniques are essentially equivalent and both enable a large depth of field and spatial-frequency multiplication for the printed pattern. The DTL scheme can be used with much smaller separations of the substrate and mask than the ATL scheme. This reduces the degradation of the pattern edges and allows more efficient utilization of the output from the light source because of the less demanding requirement on collimation. Further, the DTL technique enables the use of laser sources, which may be preferred for production processes. The light from such sources can be formed into well-collimated beams with negligible loss of power, so minimize loss of feature resolution and maximize image contrast.

The structure of the patterns printed using DTL from a particular mask pattern may also be theoretically determined using simulation software.

A limitation of the DTL technique described in U.S. Pat. Appl. no. 2008/0186579 is that the longitudinal displacement of the substrate relative to the mask during exposure should correspond accurately to an integer multiple of the Talbot distance. When the displacement is exactly an integer multiple, the average intensity distribution exposing the substrate is independent of the initial separation of the substrate and mask, and so produces a uniform exposure of the pattern features on the substrate even if the mask and substrate are not accurately flat and parallel. If, on the other hand, the displacement is not an exact integer multiple of the Talbot distance because of, for example, mechanical hysteresis or limited stepping resolution of a displacement actuator, or because of inexact synchronization between the duration of the exposure by the illumination system and the displacement of the substrate, then the average intensity distribution depends on the initial separation. In this case, if the mask and substrate are not accurately flat and parallel, then a spatial variation of feature size is introduced into the printed pattern; or if the mask and substrate are accurately flat and parallel but their separation is different for different substrates, then the size of the printed features varies from substrate to substrate; both of which may be problems for certain applications. These variations of feature size may be reduced by longitudinally displacing the substrate by a large number of Talbot distances relative to the mask, but this can introduce other problems such as degradation of the feature resolution (if the illumination beam is not well collimated), distortion of the feature shape (if the direction of displacement is not accurately longitudinal), degradation of the pattern edges (if the gap becomes too large), and disadvantageously requires larger travel range in the mechanical system.

Unpublished U.S. application Ser. No. 13/035,012, which is incorporated herein by reference, teaches a modification of the DTL technique for overcoming this limitation so as to enable periodic or quasi-periodic patterns to be printed uniformly and reproducibly without requiring the longitudinal displacement of the substrate relative to the mask during exposure to correspond accurately to an integer multiple of the Talbot distance. It further enables periodic patterns to be printed uniformly and reproducibly when the presence of 2nd or higher diffraction orders in the transmitted light-field from the mask prevents exact Talbot imaging and an exact Talbot distance. It additionally enables two-dimensional periodic patterns of features to be printed uniformly and reproducibly onto substrates when the periods of the pattern are different along different axes. It, moreover, enables a pattern of features to be printed uniformly and reproducibly onto a substrate when the period of the pattern in the mask is not constant but varies across the mask either continuously, as in a chirped grating, or step-wise. The patent application teaches that the exposure dose per incremental displacement of the substrate relative to the mask is varied during the displacement by varying the speed of displacement and/or the intensity of the exposure beam.

This modified DTL technique also has certain disadvantages. It too requires a controlled longitudinal displacement of the photo resist-coated substrate relative to the mask during the exposure and so imposes additional requirements on the mechanical structure and functionalities of the exposure system which may be difficult and costly to provide. In particular, it imposes requirements on the resolution, speed and hysteresis of the displacement of the substrate relative to the mask, and on the uniformity of the displacement over the area of the printed pattern. It also requires that the displacement is accurately orthogonal to the plane of the substrate because any lateral displacement of the substrate with respect to the mask during the exposure degrades the resolution of the printed pattern. Furthermore, since a high-resolution actuator(s), such as a piezo-electric transducer, is typically required for achieving the required displacement, and such an actuator is generally not included in standard contact or proximity mask aligners, the technique cannot be performed using those systems. The integration of high-resolution actuators in mask aligners is furthermore rendered difficult because a large displacement of the photo resist-coated substrate is generally also needed for loading and unloading of the substrates; and, moreover, the integration needs to assure that the displacement is obtained uniformly over the substrate area so that large patterns can be printed uniformly. For the case that the variation of exposure dose with incremental displacement of the substrate relative to the mask is obtained by varying the intensity of the exposure beam, it is additionally necessary that the intensity modulation is accurately synchronized with the displacement, which is difficult to obtain with the required accuracy if there is any hysteresis in the mechanical system that displaces the substrate relative to the mask.

The above-identified unpublished U.S. patent applications are hereby incorporated by reference.

It is therefore an object of the present invention to provide a method and apparatus for printing a periodic or quasi-periodic pattern of features onto a photo resist-coated substrate that possess the same advantages of the ATL technique, that is, the ability to image such patterns with a large depth of focus, and with a possible spatial-frequency multiplication of the printed pattern with respect to that in the mask, and without requiring a longitudinal displacement of the photo resist-coated substrate relative to the mask during the exposure.

It is a further objective of the present invention to enable a precise control of the averaging over the range of intensity distributions that are formed between Talbot image planes so that a dose distribution is delivered to the photo resist that is substantially insensitive to variations in the separation between the mask and the wafer, and moreover so that this insensitivity is achieved over a range of pattern types and periods simultaneously.

According to a first aspect of the present invention, a method is provided for printing a desired periodic pattern of features into a photosensitive layer, which method includes:

a) providing a mask bearing a mask pattern with a period;

b) providing a substrate bearing the photosensitive layer;

c) arranging the substrate substantially parallel to and with a separation from the mask;

d) providing a number of lasers having a plurality of different peak emission wavelengths that together emit light over a range of wavelengths;

e) forming from said light a beam for illuminating the mask with a spectral distribution of exposure dose over said range of wavelengths and having a degree of collimation;

f) illuminating the mask with said beam such that the light of each wavelength transmitted by the mask pattern forms a range of transversal intensity distributions between Talbot planes and exposes the photosensitive layer to an image component, whereby the time-integrated superposition of said components prints the desired pattern;

wherein the separation and spectral distribution are arranged in relation to the period so that the superposition of said components is substantially equivalent to an average of the range of transversal intensity distributions formed by light at any one of the wavelengths, and wherein the degree of collimation is arranged in relation to the separation so that the features of the printed pattern are resolved.

Preferably, the illumination beam is formed with a spectral distribution of intensity that has the substantially the same profile as the spectral distribution of exposure dose, and the mask is illuminated with said beam such that all the image components expose the photosensitive layer simultaneously and for the same exposure time. For this case, the spectral distribution of intensity is preferably obtained by adjusting the relative powers of the output beams from the number of laser sources. As an alternative, it may be generated by adjusting the output powers of the laser sources to substantially the same value in order to produce a combined beam with a substantially uniform spectral distribution and then directing this combined beam onto a spectral filter (e.g. transmissive or reflective) whose spectral characteristic corresponds to the required dose distribution

The illumination beam may otherwise be formed with light whose intensity at each of the peak wavelengths is substantially the same and then the mask illuminated with light of each peak wavelength for an exposure time whose dependence on wavelength corresponds substantially to the spectral distribution. Such wavelength-dependent exposure times may be obtained by including shutters in the beam paths from the individual lasers, or by switching the lasers on/off. The wavelength-dependent exposure times are preferably overlapping so as to minimize the total exposure time, in which case the intensity of the beam illuminating the mask (sum of spectral components) changes during the course of the exposure, or they may be sequential in which case the intensity of the beam may be substantially constant.

Most preferably, the separation of the mask and substrate is arranged so that varying the wavelength of illumination from λ₀−w to λ₀+w, where λ₀ is the central wavelength of the spectral distribution and 2w is the full-width at half-maximum of the distribution, causes the transversal intensity distribution illuminating the photoresist to displace longitudinally by a distance corresponding to at least the Talbot period of the intensity distribution formed by illuminating the mask at the central wavelength λ₀.

Preferably, the shape of the spectral distribution corresponds substantially to one of a truncated Gaussian profile, a truncated or non-truncated cosinusoidal profile, and a truncated or non-truncated triangular profile, or the envelope of the distribution corresponds substantially to one of said profiles.

Most preferably, the spectral distribution is smooth. Preferably, the distribution does not have multiple peaks, or is substantially without multiple peaks.

Most preferably, the beam is stationary as it illuminates the mask and its intensity is substantially uniform across the mask pattern.

As an alternative, the beam may be displaced or scanned across the pattern during the exposure. For the latter, it is advantageous if the scanning motion and cross-sectional intensity profile of the beam are arranged so that the time-integrated exposure density of the mask pattern is rendered substantially uniform. For example, the intensity profile of the beam in at least one dimension may be arranged to correspond substantially to a Gaussian distribution and the beam scanned across the mask in a raster pattern. For such a scanning exposure, it is preferable that the spectral distribution of the light is substantially uniform across the beam. Alternatively, the light from each laser source may be formed into a sub-beam of substantially collimated light and with a power dependence on wavelength that corresponds to the required spectral dose distribution, and then the illumination beam formed by combining the sub-beams such that they are spatially separated but parallel within the resulting composite illumination beam, following which the spectral distribution of dose is delivered by scanning the composite beam across the mask pattern.

The desired pattern and mask pattern may be one-dimensional, that is, a linear grating, or may be two-dimensional such as an array of features on a square, rectangular or hexagonal grid.

The desired pattern and mask pattern may not be exactly periodic but may be quasi-periodic, that is, with a period that varies slowly over the pattern area such that locally the desired and mask patterns can be considered as exactly periodic.

The mask may contain a plurality of periodic patterns with the same or different periods for printing a plurality of desired patterns with the same or different periods.

According to a second aspect of the present invention, an apparatus is provided for printing a desired periodic pattern of features into a photosensitive layer, which apparatus includes:

a) a mask bearing a mask pattern with a period;

b) a substrate bearing the photosensitive layer;

c) a means for arranging the substrate substantially parallel to the mask and with a separation;

d) a number of lasers having a plurality of different peak emission wavelengths that together emit light over a range of wavelengths;

e) a means for forming from said emitted light an illumination beam having a range of wavelengths for exposing the photosensitive layer to a pre-determined spectral distribution of exposure dose and having a degree of collimation;

f) a means for illuminating the mask with said beam such that the light of each wavelength transmitted by the mask pattern forms a range of transversal intensity distributions between Talbot planes and exposes the photosensitive layer to an image component, whereby the time-integrated superposition of said components prints the desired pattern;

wherein the separation and the spectral distribution are arranged in relation to the period so that the superposition of said components is substantially equivalent to an average of the range of transversal intensity distributions formed by light at any one of the wavelengths, and the degree of collimation is arranged in relation to the separation so that the features of the desired pattern are resolved.

Preferably, the beam-forming means includes a means for combining the output beams from the plurality of laser sources into a single beam to produce an output beam whose spectral distribution is substantially uniform across the beam, and includes a means for collimating the light of the single beam to form the illumination beam.

Advantageously, the output beams from the laser sources are combined by coupling them into an optical fibre of sufficient length so that the propagation of the light through the fibre causes a thorough mixing of the light of the different wavelengths, thereby generating an output beam from the fibre whose spectral distribution is substantially spatially uniform. Advantageously, the light from the output face of the fibre is collected and focussed by a lens, by a system of lenses, or by other optical element(s) onto an array of micro-lenses. Most advantageously it is a tandem array. In the case that an array of cylindrical micro-lenses is employed, it is preferable that the transmitted light then passes through a second such array orientated orthogonal to the first, so that the pair of arrays produces divergent light with a square or rectangular illumination field with substantially uniform intensity. This light is then preferably collimated to form the illumination beam for illuminating the mask. As an alternative, a single array of cylindrical micro-lenses may be employed to produce divergent light with substantially uniform intensity in one direction, which is then collimated to produce an illumination beam that is scanned across the mask to produce a uniform time-integrated exposure of the mask pattern. As another alternative, an array of spherical micro-lenses may be employed to produce divergent light with a circular illumination field with substantially uniform intensity, which is subsequently collimated to form the illumination beam for illuminating the mask.

Alternatively, the output beams from the laser sources may be combined by coupling them directly into an array of micro-lenses, which is advantageously a tandem array. In the case that an array of cylindrical micro-lenses is employed, it is preferable that the transmitted light passes through a second such array orientated orthogonal to the first, so that the pair of arrays produces divergent light with a square or rectangular illumination field with substantially uniform intensity, and that this light is then collimated to form the illumination beam, which preferably remains stationary with respect to the mask during the exposure. In the case that a single array of cylindrical micro-lenses is employed, it is preferable that the divergent light from the array is collimated to form an illumination beam that is substantially uniform in one direction, and that this beam is then scanned across the mask to produce a uniform exposure of the mask pattern. A single array of spherical micro-lenses may alternatively be used to produce divergent light with a circular illumination field, which is then collimated to form an illumination beam with substantially uniform intensity that preferably remains stationary with respect to the mask during the exposure.

Preferably the laser sources are laser diodes whose output wavelengths are advantageously selected to be substantially equally spaced over the wavelength range.

Advantageously, means are included for varying the temperatures and/or drive currents of the laser diodes during the exposure to smoothen the time-integrated spectral distribution of exposure dose delivered by the illumination beam during the course of the exposure.

The mask may be an amplitude mask in which the features of the periodic pattern are formed as openings in an opaque material, or may be a phase-shift mask in which the features are formed as openings of constant or different depths in a transparent or partially transparent material.

Preferred examples of the present invention are hereinafter described with reference to the following figures:

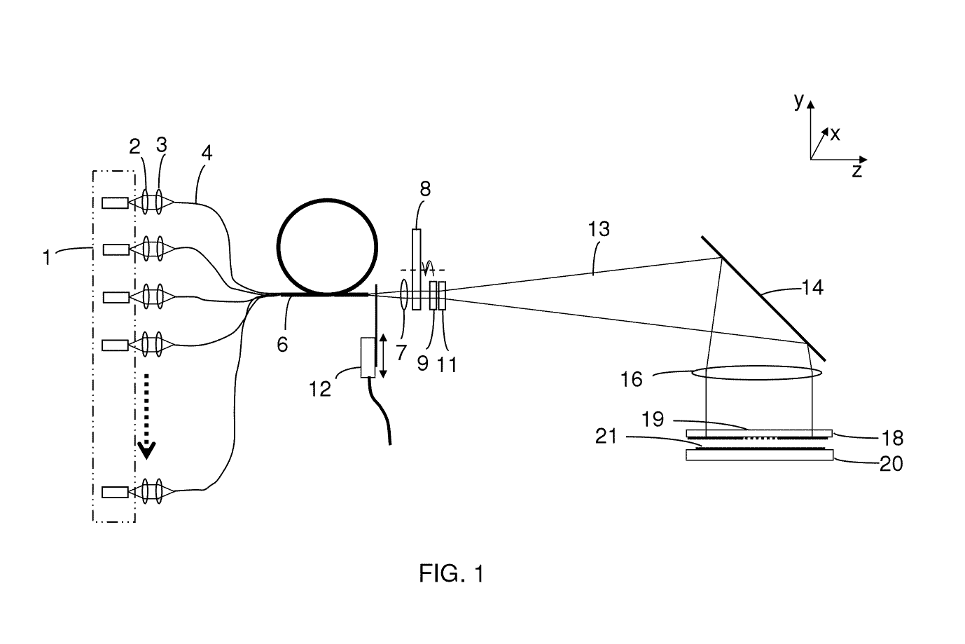

FIG. 1 illustrates a first embodiment of the invention.

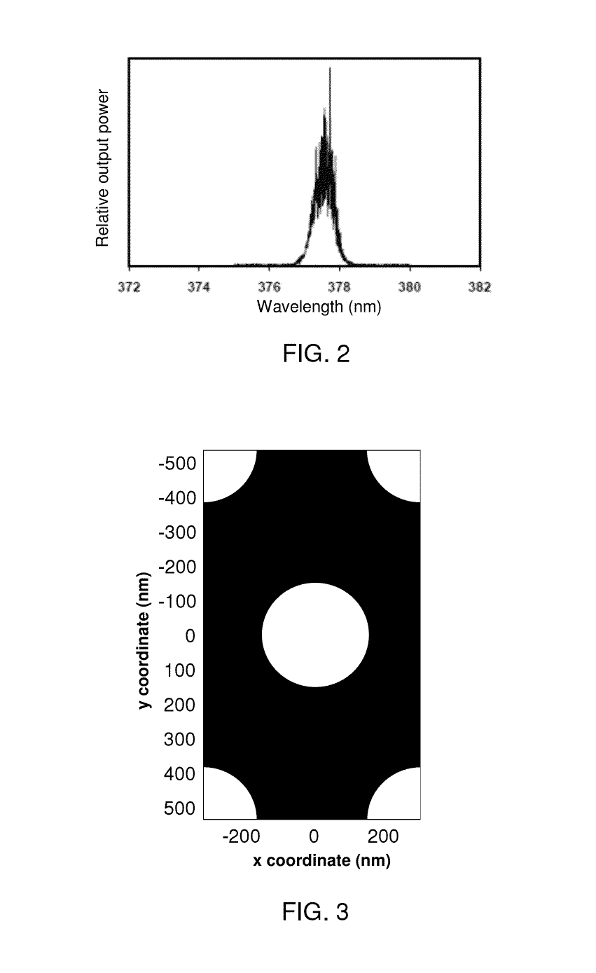

FIG. 2 shows a typical spectral profile of the output beam of a laser diode

FIG. 3 illustrates the unit cell of a periodic pattern in a mask employed in the first embodiment

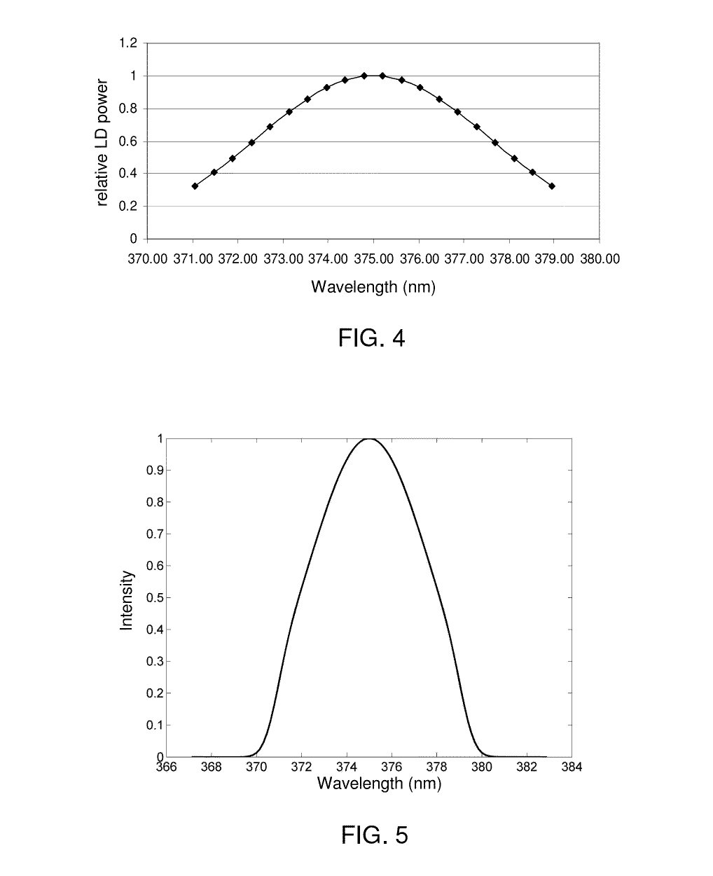

FIG. 4 shows the relative output powers of an array of laser diodes employed in the first embodiment and their dependence on the emission wavelength

FIG. 5 illustrates the integrated spectral distribution produced by the array of laser diodes employed in the first embodiment

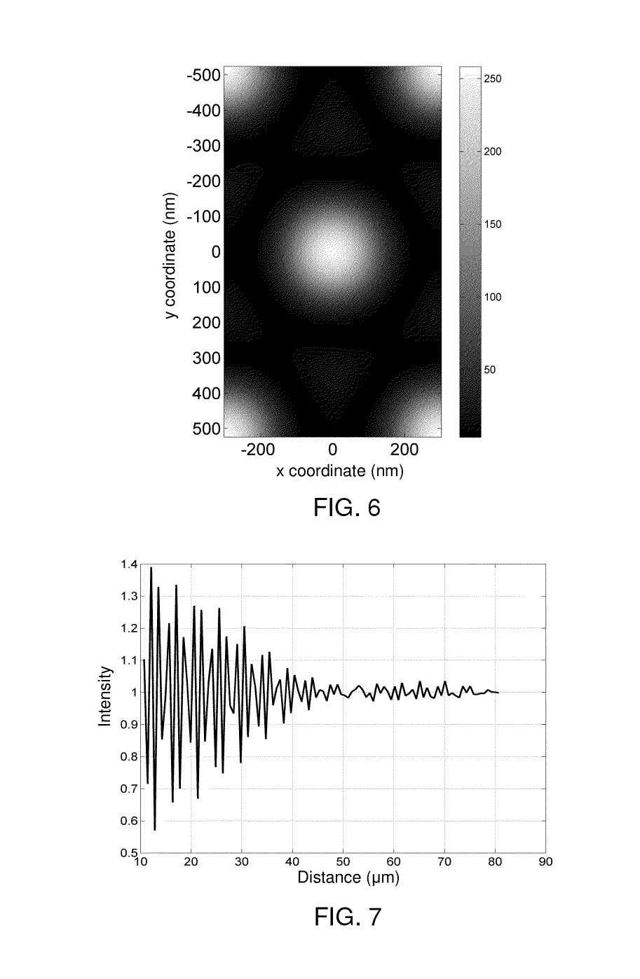

FIG. 6 shows a computer simulation of the integrated intensity distribution exposing the photoresist produced using the apparatus of the first embodiment

FIG. 7 shows the calculated dependence of the intensity at the centre of the integrated intensity distribution exposing the photoresist on the separation of the photoresist-coated substrate and the mask

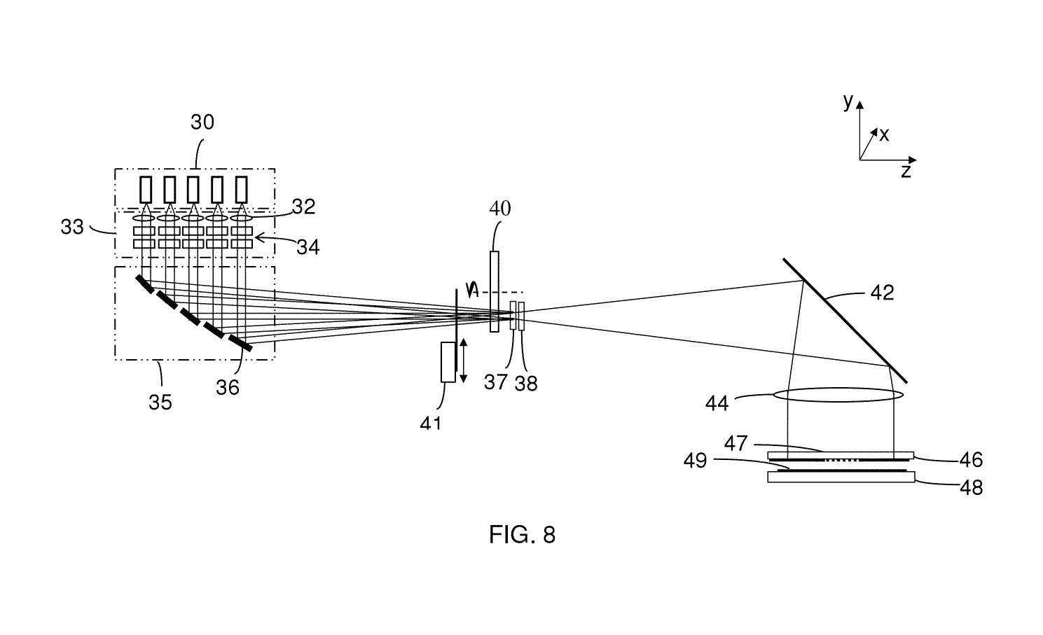

FIG. 8 illustrates a second embodiment of the present invention

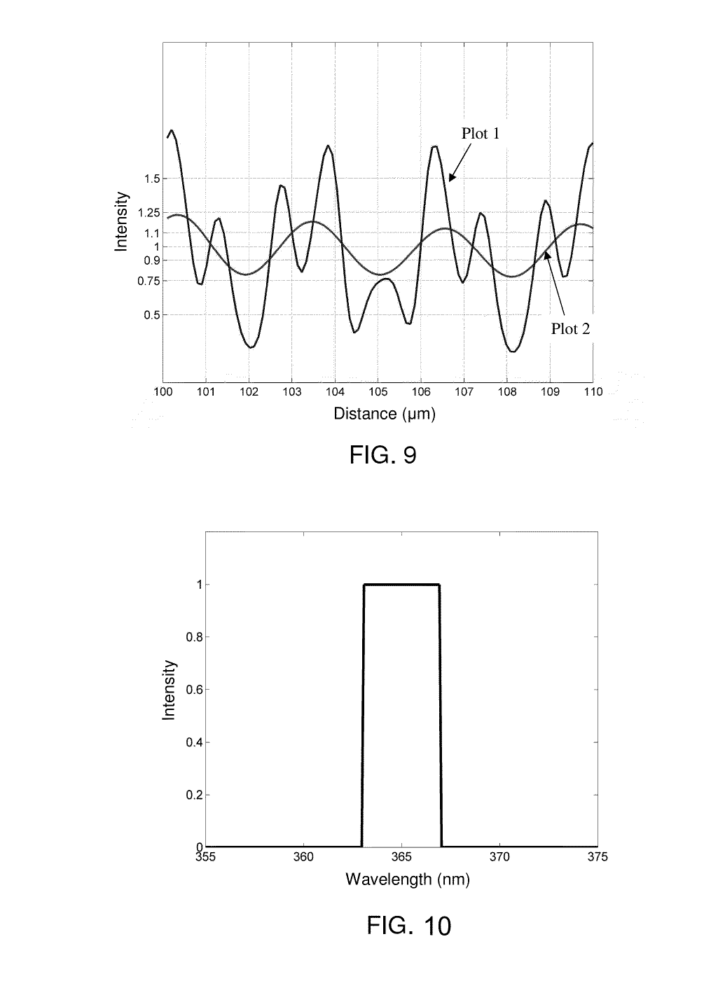

FIG. 9 shows computer-simulated dependencies of the intensity at particular transversal coordinates in a light-field transmitted by a hexagonal pattern in a mask on distance from the mask for the two cases of monochromatic illumination and illumination having a Gaussian spectrum.

FIG. 10 shows a spectral distribution employed for illuminating a hexagonal pattern of holes in a mask.

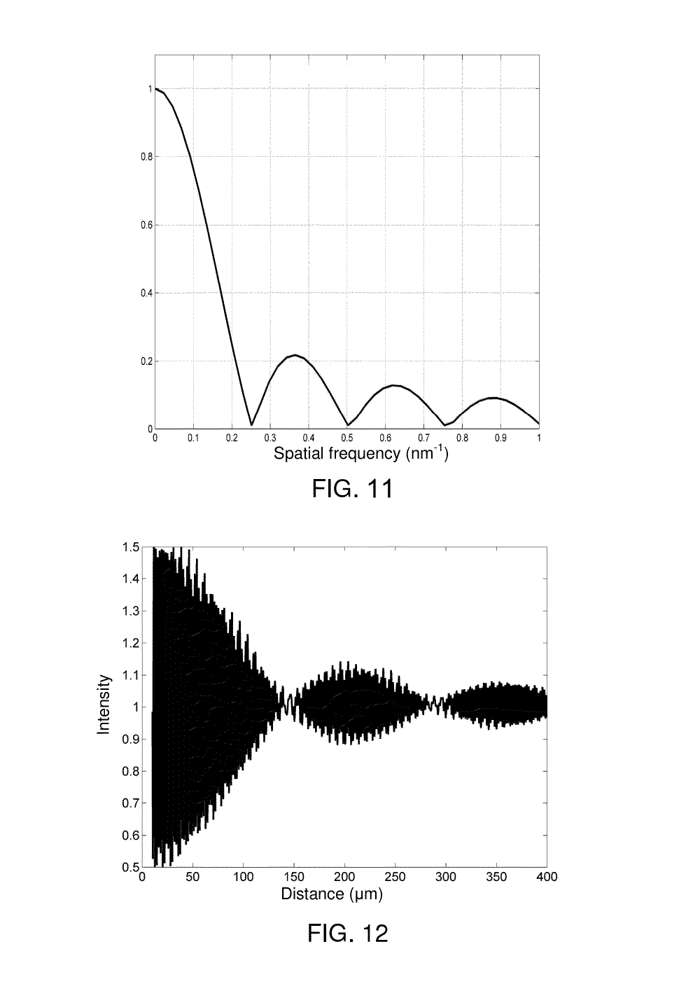

FIG. 11 shows the Fourier transform of the spectral distribution of FIG. 10.

FIG. 12 shows a computer-simulated dependence of the intensity in the light-field transmitted by the hexagonal pattern illuminated by the spectral distribution of FIG. 10 on distance from the mask and at transversal coordinates corresponding to the centre of one of the holes in the pattern.

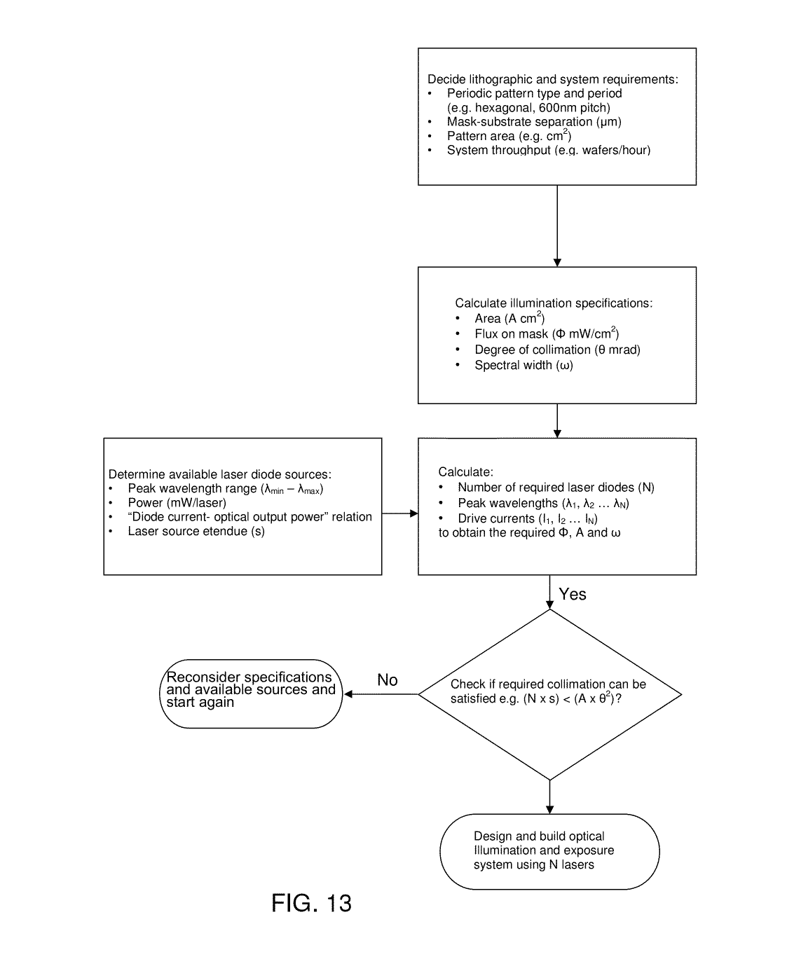

FIG. 13 illustrates an exemplary sequence of procedural steps for applying the present invention to the design of an exposure system for a manufacturing process

In a first exemplary embodiment of the present invention, with reference to FIG. 1, an illumination source comprises an array of twenty laser diodes 1 each of which has its own control circuitry to enable its output power to be independently adjusted. The laser diodes (LDs) have been selected so that their central or peak wavelengths are approximately equally spaced over the spectral range 371-379 nm, i.e. are spaced by ˜0.4 nm, and the spectral bandwidth of each LD is typically ˜1 nm, as illustrated by the spectral profile shown in FIG. 2. LDs emitting in multi-transverse mode are employed to enable up to ˜200 mW of output power per LD. Such LDs may be obtained from, for example, Nichia Corporation. The divergent and polarized output beam from each LD is collimated by a lens 2 (this lens, as for other lenses in the figures illustrating the embodiments of the invention, is shown schematically and may comprise, for example, a multi-element lens or a GRIN lens) and then focussed by a second lens 3 to couple the light into an optical fibre 4 with a core diameter of ˜0.1 mm. The other ends of the optical fibres are bundled together and the emerging light is coupled via an adaptor into a single fibre 6 with a core diameter of ˜0.7 mm and with an NA=0.2. The fibre 6 has length >2 m and is arranged in a loop so that the spectral components are mixed well as they propagate through it so that the spectral distribution of the beam emerging from the output face of the fibre 6 is substantially uniform. The transmission of the light along the fibre also depolarizes the output beam. The intensity of the output beam reduces with increasing cone angle of the divergent rays such that the FWHM cone angle of the distribution is ˜10° (FWHM).

The light from the output face of the fibre 6 is collected by a lens 7 which forms an illumination spot of diameter ˜1.5 mm on a first tandem array of cylindrical micro-lenses 9. The array 9 is orientated to refract the light in yz plane, and the numerical aperture of the micro-lenses is such that they refract the light over a range of angles of ˜±7°. The transmitted beam is subsequently incident on a second, identical micro-lens array 11 that is located in proximity and orthogonally to the first array 9 so that it refracts light over a range of angles of ˜±7° in the xz plane. The two arrays 9, 11 thus produce a square distribution of light in the far field whose intensity and spectral distribution are substantially uniform. A diffuser 8 may be included in the optical path before (or after) the micro-lens arrays 9, 11 in order to reduce the spatial coherence of the incident light and suppress undesirable interference effects caused by the periodic structure of the micro-lens arrays 9, 11. The diffuser 8 should be mounted to a motor (not shown) for rotating it about an axis parallel to the beam direction during the lithographic exposure so as to render the time-integrated exposure uniform. An electronically-operated shutter 12 is additionally included in the beam-path between the fibre 6 and the collimating lens 7 to enable the duration of the photolithographic exposure to be accurately and reproducibly controlled. The divergent beam from the micro-lens arrays 9, 11 is reflected by a mirror 14 towards a lens 16 that collimates the light before it illuminates a pattern 19 in a mask 18 at substantially normal incidence. The focal length of the lens 16 is selected to be ˜0.75 m so that mask patterns up to 6″ diameter may be exposed. With this focal length the range of angles at which the light illuminates each point of the mask pattern is sufficiently small to provide the imaging resolution required for the particular application concerned. In Talbot imaging, a change in angle of the illumination beam causes a lateral displacement of the Talbot image, and so a range of angles of illumination causes a blurring of the image which, above a certain limit, results in a loss of feature resolution. With a ˜1.5 mm-diameter beam illuminating the micro-lens arrays 9, 11 and a ˜0.75 m-focal-length lens 16, the resulting range of angles of incidence at each point of the mask is ˜2 mR. The range of angles of light at each point in the illumination beam may be considered as being inversely related to the beam's degree of collimation: a smaller range of angles corresponds to a higher degree of collimation.

The mask 18 bears a two-dimensional periodic pattern 19 formed in a layer of chrome on a fused-silica substrate that has been fabricated using standard electron-beam lithography. The pattern 19 comprises an array of holes of diameter 300 nm arranged on a hexagonal grid with a nearest-neighbour distance of 600 nm, as illustrated by the unit cell shown in FIG. 3. The mask 18 is held by a vacuum chuck (not shown in the figure) that is mounted to a system of tilting and translation stages (also not shown in the figure since they are well-known to a skilled person in the art of precision mechanics for mask aligners) that allow the mask 18 to be positioned so that its lower surface is parallel to and at a particular distance from a substrate 20 located below the mask 16. The upper surface of the substrate 20 is coated with a layer of a standard i-line sensitive photoresist 21. The substrate 20 is mounted to another vacuum chuck (also not shown) so that its upper surface is substantially flat. The mask 18 is arranged substantially parallel to and at a distance from the substrate 20 using standard measuring means for determining the separation between two substrates arranged in proximity. For example, reference gauges with a range of thicknesses may be introduced between the edges of the mask 18 and substrate 20 or, preferably, an optical interferometric measurement system (for example, one based on white-light, or broad-band, interferometry) may be employed to make local measurements of their separation at different locations over the mask pattern 19.

In order to generate a particular spectral distribution of the light at the output end of the fibre 6 the power of the spectral component of the beam from each LD is measured by, firstly, interposing a detector in the beam path after the collimating lens 7, and then switching on, in turn, each LD with the others switched off, and adjusting the drive current of each LD to obtain a beam with the required output power (the output powers of the individual LDs may be alternatively measured by including a shutter between the collimating lens 2 and focusing lens 3 for each LD and opening the shutter for each in turn with the others closed whilst measuring with the detector after the lens 7; or, alternatively, by simultaneously measuring the output powers of all the LDs by determining the spectral composition of the beam after lens 7 using a spectrometer). Specifically, the output powers of the LDs are adjusted so that the dependence of output power, P, on emission wavelength, λₙ, is substantially described by a truncated Gaussian distribution:

$$P ( {λ}_{n} ) = {P}_{0} exp \{ \frac{- {( {λ}_{n} - {λ}_{0} )}^{2}}{2 {σ}^{2}} \} , \\ with \\ \vert {λ}_{n} - {λ}_{0} \vert \leq t σ \qquad equ . ( 3 )$$

where exp( ) represents the exponential function, λ₀ is the wavelength at the centre of the range, a is the standard deviation of the Gaussian distribution and t is a truncation parameter that is preferably ≧1.

In view of the range of wavelengths available from the LD array 1 employed in this embodiment, σ and t are selected to be 2.6 nm and 1.5 respectively. With these values the dependence of the output powers of the LDs on their central wavelengths is as shown in FIG. 4. If the spectral bandwidth from each LD is ˜1 nm, then the integrated spectral composition of the light emerging from the fibre 6 is as shown in FIG. 5. The full-width at half-maximum (FWHM) of this distribution, which deviates somewhat from the pure Gaussian form, is determined to be 6.2 nm.

The separation of the photo resist-coated substrate 20 and mask 18 is adjusted in order that the illumination forms a stationary image at the photo resist 21. With the above-described quasi-Gaussian distribution, a substantially stationary image is formed if the separation is such that (hypothetical) illumination of the mask by a monochromatic beam whose wavelength is varied from λ₀−w to λ₀+w, where 2w is the FWHM of the distribution, would cause the transversal intensity distribution illuminating the photoresist 21 to displace longitudinally by a distance corresponding to at least the Talbot period of the intensity distribution formed by illuminating with the central wavelength λ₀. This may be represented mathematically as

$$2 w \frac{δ}{δλ} {\{ \frac{d}{T ( λ )} \}}_{λ = {λ}_{0}} \geq 1 , \qquad equ . ( 4 )$$

where T(λ) describes the dependence of the Talbot period on the illumination wavelength λ, and d is the separation of the mask and substrate.

The Talbot period is related to the wavelength by

$$T ( λ ) = \frac{λ}{1 - cos ϕ ( λ )} , \qquad equ . ( 5 )$$

where φ(λ) is the polar angle of the first diffraction order from the periodic pattern in the mask.

In the case of a hexagonal array of pattern features with a nearest-neighbour distance, p, the polar angle of the 1st diffraction order is given by

$$sin ϕ ( λ ) = \frac{2 λ}{\sqrt{3} p} , \qquad equ . ( 6 )$$

From equs. (4)-(6) it can be derived that a stationary image is formed at the photoresist if the separation between substrate and mask is arranged so that

$$d \geq \frac{{λ}_{0}^{2}}{2 w} {\{ \frac{2 {λ}_{0} tan ϕ ( {λ}_{0} )}{\sqrt{3} p} + cos ϕ ( {λ}_{0} ) - 1 \}}^{- 1} , \qquad equ . ( 7 )$$

Evaluating this with the particular parameter values employed in this embodiment (λ₀=375 nm, p=600 nm and 2w=6.2 nm) yields φ(λ₀)=46.2°, and hence d≧50 μm. Clearly, if the FWHM of the spectral profile formed from the laser sources employed is instead 3.1 nm, then twice the separation of mask and substrate would be required. The separation between mask and substrate should preferably be arranged accordingly; however, depending on the uniformity of size of printed features required for the particular application, somewhat smaller separations may be employed.

Equ. (7) assumes that the mirror 14 reflects all spectral components of the incident beam with equal efficiency and that all the other optical elements between the LD array 1 and mask 18 transmit the spectral components with equal efficiency, such that that the spectral distribution illuminating the mask corresponds to that emitted by the LD array 1. If, in other embodiments of the invention, the optical elements between the LD array and mask do not reflect and/or transmit the light with equal efficiency, then the output powers of the individual LDs should be adjusted appropriately in order to compensate the spectral modulation introduced by the optics, and the parameter w in equ. (7) should instead refer to the HWHM of the spectral distribution illuminating the mask rather than to the distribution emitted by the LD array.

In order that the required resolution of feature can be printed into the photo resist, the illumination beam needs to be well collimated; in particular, the range of angles of the rays, Δω (FWHM), illuminating any point of the mask pattern should preferably satisfy

$$Δ ω \leq \frac{L}{3 d} \qquad equ . ( 8 )$$

where L is the desired feature size in the printed pattern and d is the separation of the mask and substrate.

In this embodiment, the required feature size in the printed pattern is the same as the diameter of the holes in the hexagonal array of the mask pattern; and so, if the separation of the mask and substrate is set at ˜50 μm, then using equ. (8), the range of angles of incidence illuminating each point of the mask pattern should be 2 mR (FWHM).

The degree of collimation provided by the above-described optical system is ˜2 mR, and so is sufficient to enable the ˜300 nm features of the stationary image printed into the photo resist 21 to be resolved. A higher degree of beam collimation would enable even better definition of the features.

This minimum separation required between mask 18 and substrate 20 for printing a stationary image into the photo resist 21 may be determined and/or verified by computer simulation of the light-field transmitted by the mask 18. For this, a standard methodology such as finite difference time domain (FTDT) or rigorous coupled wave analysis (RCWA) may be employed using such commercially or freely available software as GSolver developed by Grating Solver Development Company, or MEEP developed by the Massachusetts Institute of Technology. The application of such simulation tools to photolithographic exposure by ATL and DTL techniques is described in more detail in co-pending U.S. application Ser. No. 12/903,389. Computer simulation of the integrated intensity distribution at the photo resist layer 21 formed by illuminating the mask pattern 19 with the exposure beam of this embodiment and using a mask-to-substrate separation of 50 μm is shown in FIG. 6. From the intensity scale in the figure, it can be seen that the intensity peaks in the distribution have high contrast, and so enable a robust lithographic process for device manufacture. To verify that the intensity distribution is indeed stationary, i.e. invariant to further increase in separation between substrate 20 and mask 18 so as to enable a large depth of focus, the intensity at the centre of the distribution is calculated as a function of increasing separation between mask 18 and substrate 20. From the result shown in FIG. 7, it can be seen that the intensity varies rapidly for small separations but reaches an essentially stable value (residual variation <±2%) when the separation >−50 μm, thereby confirming the minimum required separation calculated from equs. 4-6.

Exposure is performed by opening and later closing the shutter 12 so that the mask 18 is illuminated by the collimated beam for an exposure time to deliver a certain exposure energy density (i.e. exposure dose). Since the photo resist is simultaneously exposed to all wavelength components in the beam, the spectral distribution of the exposure dose corresponds to the spectral intensity distribution of the beam (i.e. they have the same profile), and the total exposure dose is the integral of the dose spectral distribution, which is proportional to the exposure time. The exposure time is adjusted so that the exposure dose forms the desired structures in the developed photo resist 21. This may be determined using standard photolithographic techniques such as exposing a number of photoresist-coated substrates with a range of exposure doses and evaluating the printed patterns by optical or scanning electron microscope to determine the optimum dose.

Analogously to the teaching of U.S. application Ser. No. 13/035,012, in which substantially the same advantages and printed results are achieved by varying the exposure dose per incremental displacement of the photo resist-coated substrate according to truncated-Gaussian, a truncated-sinusoidal and truncated-triangular profiles, substantially the same advantages and printed results as illustrated above may be achieved by alternatively arranging that the dependence of the output powers of the LDs on their respective output wavelength conforms instead to one of a (un)truncated-sinusoidal and a (un)truncated-triangular profile, so that the spectral distribution of the light illuminating the mask is similarly described. For the former case, the output powers of the LDs, P(λₙ), should be adjusted so that their dependence on emission wavelength, λₙ, is described by

$$P ( {λ}_{n} ) = {P}_{0} {cos}^{2} \{ \frac{π ( {λ}_{n} - {λ}_{0} )}{4 w} \} , \\ with \\ \vert {λ}_{n} - {λ}_{0} \vert \leq 2 tw \qquad equ . ( 9 )$$

where λ₀ is the central wavelength of the range, 2w is the FWHM of the untruncated function, and t is a truncation parameter whose value is preferably ≧1.

With a (un)truncated sinusoidal profile, a stationary image is formed at the photoresist if the separation, d, is arranged so that changing the illumination wavelength from λ₀−w to λ₀+w causes the transversal intensity distribution illuminating the photoresist to displace longitudinally by a distance corresponding to at least the Talbot period of the intensity distribution formed by light at the central wavelength λ₀. This occurs when equ. (4), with parameter w therein referring instead to the half-width at half maximum (HWHM) of the (un)truncated sinusoidal profile, is satisfied.

The minimum separation required between the mask and substrate for forming the stationary image from a hexagonal array of features in the mask may therefore also be calculated using equ. (7).

For the case of an (un)truncated triangular profile, the output powers of the LDs, P(λₙ), should be adjusted so that their dependence on emission wavelength, λₙ, is described by

$$P ( {λ}_{n} ) = {P}_{0} ( 1 - \frac{\vert {λ}_{n} - {λ}_{0} \vert}{2 w} ) , \\ with \\ \vert {λ}_{n} - {λ}_{0} \vert \leq 2 tw \qquad equ . ( 10 )$$

where λ₀ is the central wavelength of the range, 2w is the FWHM of the untruncated function, and t is a selectable truncation parameter that is preferably close to and less than 1.

With a (un)truncated triangular profile, a stationary image is formed at the photoresist if the separation, d, is arranged such that changing the illumination wavelength from λ₀−w to λ₀+w causes the transversal intensity distribution illuminating the photoresist to displace longitudinally by a distance corresponding to at least the Talbot period, T, of the intensity distribution formed by light at the central wavelength λ₀. This occurs when equ. (4), with parameter w therein referring instead to the HWHM of the (un)truncated triangular profile, is satisfied.

The minimum separation required between the mask and substrate for forming a stationary image from a hexagonal array of features in the mask may therefore be likewise calculated using equ. (7).

Thus, spectral distributions with Gaussian, (un)truncated sinusoidal and (un)truncated triangular profiles with the same value of FWHM produce stationary images at substantially the same distance from the mask and result in substantially the same printed patterns in the photo resist.

The shapes of the preferred truncated Gaussian, (un)truncated triangular and (un)truncated sinusoidal profiles described above are similar in that all are smooth functions of wavelength with a central peak and have a full width that is approximately double their FWHM value. It should therefore be understood from the foregoing that other shapes of spectral distributions that are similar to these may be alternatively employed in other embodiments of the present invention with the expectation of obtaining substantially the same advantages and printed results. For example, a spectral distribution with a suitable trapezoidal profile may be employed. With such an alternative distribution, the minimum separation between mask and photo resist-coated substrate during exposure should preferably be determined from the FWHM value of the spectral distribution using equ. (7) and/or by computer simulation. A complementary method for estimating the stabilization distance at which the ATL image is formed, which considers the Fourier transform of the spectral distribution, is described later in the description.

Ii is preferable that secondary and multiple peaks are suppressed in the spectral distribution of the illumination beam and/or in the spectral distribution of the exposure dose. For this reason it is advantageous that the spectral width of the beams from the individual laser sources is larger than the spectral separation of their peak wavelengths when ordered in sequence of increasing wavelength, so that there is substantial overlap between the superposed spectral profiles.

If, in the above embodiments, the pattern in the mask is instead a two-dimensional array with another symmetry, such as a square array or a honeycomb array, or is a one-dimensional array of alternating parallel lines and spaces, the equivalent form of equ. (7) corresponding to the array type concerned should rather be derived and employed.

If the mask bears a one-dimensional array, then it can be advantageous to include a polarizer in the path of the spectrally-mixed beam. By polarizing the light illuminating the mask in the direction parallel to the grating lines, the contrast of the integrated intensity distribution exposing the photo resist is enhanced, which enables better definition of the printed features.

In a second embodiment of the invention, with reference to FIG. 8, an illumination source comprises a two-dimensional, 4×5 array of twenty laser diodes 30 each of which has its own control circuitry to enable its output power to be independently adjusted. The LDs have been selected so that their central or peak wavelengths are approximately equally spaced over the spectral range 371-379 nm, i.e. are spaced by ˜0.4 nm, and the spectral bandwidth of each LD is typically ˜1 nm. The beam from each LD, which diverges more quickly in the xy plane than in the yz plane, is incident on a lens 32 that collimates the light to produce a beam with elliptical cross-section. The beam then passes through on an anamorphic prism pair 34 that compresses the beam in the xy plane to produce a collimated beam with substantially circular cross-section and diameter ˜1 mm. The collimated beam from each LD is deflected by a mirror 36 so that it illuminates a first tandem array of cylindrical micro-lenses 37. The beams from the other LDs in the array 30 are similarly collimated and circularized by corresponding lenses and anamorphic prism pairs in a beam-shaping array 33 and are subsequently deflected by corresponding mirrors in a mirror array 35, so that all the beams are substantially superposed to form an illumination spot of diameter ˜2 mm at the micro-lens array 37. The numerical aperture of the micro-lenses is such that they refract light over a range of angles of ˜±7°, and the array 37 is orientated so that the light is refracted in the yz plane. The divergent light from the first micro-lens array 37 is immediately incident on a second, identical array 38 that is orientated in the orthogonal plane which refracts light over a range of angles of ˜±7° in the xz plane. The divergent light from the two arrays 37, 38, which also act as beam combiners, therefore produces a square distribution of light in the far-field whose intensity and spectral distribution are substantially uniform. To avoid the problem of “cross-talk” in the emergent light, the convergence angles of the beams incident on the micro-lens arrays 37, 38 are arranged to be <±7° in both xz and yz planes. This is facilitated by arranging that the LDs in the array 30, the lenses and anamorphic prisms in the beam-forming array 33, and the mirrors in the array 35 are arranged in 2-dimension configurations rather than in single rows. A diffuser 40 is preferably included in the optical path before the micro-lens arrays 37, 38 in order to reduce the spatial coherence of the light in each beam illuminating the periodic structure of the micro-lens arrays 37, 38 so as to suppress undesirable interference effects in the output beam. The diffuser 40 is mounted to a motor (not shown) so that it can be rotated about an axis orthogonal to the planes of the micro-lens arrays 37, 38 during the lithographic exposure so as to render the time-integrated exposure uniform. An electronically-controlled shutter 41 is additionally included before the diffuser 40 to enable the beams from the LDs in the array 30 to be simultaneously blocked, so that the duration of the lithographic exposure can be accurately and reproducibly controlled. The divergent beam from the micro-lens arrays 37, 38 is reflected by a mirror 42 towards a lens 44 that collimates the light before it illuminates at substantially normal incidence a pattern 47 in a mask 46. The mask pattern 47 is the same as employed in the first embodiment. In view of the diameter of the integrated beam illuminating the tandem arrays 37, 38, the focal length of the collimated lens 44 is selected to be ˜1 m so that the range of angles of the light illuminating each point of the pattern in the mask is ˜2 mR.

Below the mask 46 is a photo resist-coated substrate 48 that is arranged substantially parallel and in proximity to the mask 46 using the same mechanical devices and gap-measuring methods as employed in the first embodiment.

The spectral distribution of the light illuminating the mask 46 is adjusted to substantially the same distribution as employed in the first embodiment. This may be achieved in an equivalent way, by using a detector to measure the power of the collimated beam from each LD, and them adjusting the output power of each LD to the required value using its control circuitry. The separation of the mask 46 and photo resist-coated substrate 48 is adjusted to the same value of ˜50 μm needed for forming a stationary image of the mask pattern and for ensuring that the features of the printed pattern are well-resolved given the degree of collimation provided in the illumination beam. The exposure is conducted using essentially the same procedures as in the first embodiment.

If the mask pattern is two-dimensional, as is the case with a hexagonal array, it can be advantageous to include polarization-changing components in the optical system so that the beam illuminating the mask is not linearly polarized. By including a quarter-wave retarder or depolarizer in the collimated, linearly-polarized beam from each LD, the polarization of the beam illuminating the mask is distributed isotropically, which facilitates the formation of rotationally symmetric features, such as circular holes, in the photo resist.

In another embodiment, the LDs in the array are arranged with different orientations so that the beam illuminating the mask is not linearly polarized. For example, half of the LDs may be mounted by rotating them by 90° about the axis parallel to the direction of their output beam, so that half of the light in the beam illuminating the mask is polarized in one plane and the other half in the orthogonal plane; thereby providing substantially the same advantage for printing a two-dimensional pattern of rotationally symmetric features.

If, on the other hand, the pattern in the mask is one-dimensional it is preferable that the beam illuminating the mask is plane-polarized in order to ensure that the stationary image has high contrast.

In another embodiment of the invention, the number of LDs employed is 2n with output wavelengths equally spaced by ˜Δλ/(n−1) over a range, Δλ, and two LDs are employed for each wavelength value. Analogously, in other embodiments, the number of LDs employed is 3n or 4n (or higher multiples) with output wavelengths equally spaced by ˜Δλ/(n−1) over a range, Δλ, and three or four LDs respectively are employed respectively for each wavelength value.

Whereas the laser sources in the above embodiments are selected so that their central wavelengths are equally spaced over a range and their relative output powers are adjusted according to the required spectral distribution, in another embodiment of the invention the lasers are selected so that the number of lasers per unit wavelength interval varies over the range of wavelengths and their output powers are preferably adjusted to substantially the same value, so that the integrated spectral distribution of the combined beams corresponds to the desired quasi-Gaussian or other profile.

In another embodiment of the invention, the output powers of the LDs are adjusted to substantially the same value, and the output beams are directed, preferably after first combining and collimating them, through a filter whose spectral transmission curve corresponds to the required distribution; and the transmitted beam is employed to illuminate the mask. In a similar and equivalent embodiment, the output beams are directed, preferably after first combining and collimating them, onto a reflection filter whose spectral reflectance curve corresponds to the required distribution; and the reflected beam is employed to illuminate the mask.

Whereas the illumination beams in the above-described embodiments are stationary during the exposure, which is preferable, they may be alternatively scanned across the mask during the exposure. In this case it is preferable that the cross-sectional intensity profile of the beam and the scanning motion are arranged so that the time-integrated exposure density over the mask pattern is rendered substantially uniform.

In a further embodiment of the invention, the desired variation of exposure dose with illumination wavelength is wholly or partly obtained by a variation of the exposure time of the mask to the different wavelengths. This may be performed by, for example, adjusting the power of the output beam from each of the LDs to substantially the same value, and then arranging, by means of independently controlled shutters included in the beam paths from the LDs (or, alternatively, by individually switching each of the LDs on/off) that the exposure time of the mask to the light from each LD varies with wavelength according to, for example, a quasi-Gaussian distribution. The periods of time during which the light of the different wavelengths illuminate the mask are preferably overlapping so that the total exposure time is minimized, although alternatively they may be in series. In a variant of this embodiment, the beam from each LD has substantially the same instantaneous power but the light is delivered in pulses of preferably constant frequency and with a duty cycle (which determines the time-averaged power) that varies with wavelength according to the desired quasi-Gaussian or other distribution. Such a pulsing of the beam from each LD may be achieved by means of an electronically-controlled shutter included in the beam path or by switching on/off the LD. The pulsing may alternatively be between high and low values of power rather than between a high value and zero. An analogue modulation of the power from each LD may be employed for the same purpose.

In another embodiment the beams from the individual LDs are not superposed into a single substantially homogenous beam as described in the above embodiments, but are combined into a composite beam in which the collimated sub-beams from the different LDs remain spatially distinct and are substantially parallel, and the dependence of the power of light in the sub-beams on wavelength is arranged to correspond to the required spectral distribution of dose. The lithographic exposure is performed by scanning this composite beam across the mask at a constant angle of incidence so that the mask pattern is uniformly exposed to each of the sub-beams at the different wavelengths, and consequently uniformly exposed to the desired spectral distribution. With this embodiment the mask pattern is exposed to the different wavelengths in a sequential manner rather than simultaneously.

In another embodiment of the invention, the temperature of each LD is individually adjusted using an independent cooling mechanism (such as thermo-electric cooling) in order to fine-tune the central wavelength of its output beam to the required value so that, for example, the central wavelengths of the LDs are accurately equally spaced over the range. Alternatively, the temperature of the LDs may be oscillated between a higher and a lower value during the exposure in order to broaden the time-integrated spectrum of each LD, thereby reducing the number of LDs required to form a composite beam with a quasi-Gaussian, or similar, spectral profile having a desired FWHM. Such a temperature oscillation of the LDs may also be employed to suppress the effects of possible fine structure in the spectra of the individual LDs so that the composite, time-integrated spectrum from the multiple LDs approximates more closely to the desired profile. In addition, it enhances the overlap between the spectra of the individual LDs, thus suppressing or even eliminating secondary or multiple peaks in the integrated spectrum.

A similar broadening of the time-integrated spectra of the individual LDs and/or suppression of fine structure may be alternatively obtained by oscillating the drive current of the LDs during the exposure. The shape of the time-integrated spectrum from each LD may be further modified according to the requirement by selecting the profile of drive current variation in each oscillation.

In another embodiment, the offsets of the actual central wavelengths of the laser sources from the values desired for arranging that they are, for example, equally spaced over the range are compensated to some extent by adjusting the relative powers of the output beams (so that the power distribution is not exactly that calculated assuming equal spacings of the wavelengths) in order that the integrated spectral distribution of the combined beams approximates well to the desired profile.

Whereas the LDs selected for the above-described embodiments emit light in multi-transverse mode in order that the output beams have relatively high power, which is an advantage for minimizing the exposure time of the mask and the photoresist, lasers that emit beams in single transverse mode may be alternatively employed in other embodiments.

Whereas an optical fibre and micro-lens arrays are respectively employed in the above embodiments for combining the light emitted from the different lasers sources into a single, spectrally homogenous beam for illuminating the periodic pattern in the mask, it should be understood that in other embodiments of the invention other types of beam-combining means may be employed to achieve the same or similar result.

Similarly, whereas micro-lens arrays are employed in the above embodiments to produce an illumination beam with a high uniformity of intensity across the mask pattern, in other embodiments other means may be employed for the same purpose. For example, the divergent beam from the fibre 6 of the first embodiment, which has a substantially Gaussian angular distribution, may be first collimated and then directed through a refractive Gaussian-to-rectangular beam transformer that produces an output beam with a substantially uniform intensity distribution, and then this beam is further expanded to provide the beam size and degree of collimation necessary for illuminating the mask.

Whereas the optical systems between the laser sources and mask in the above-described embodiments are devised and employed for combining the beams from a number of lasers having different wavelengths in order to form a uniform beam with a larger spectral bandwidth than that of the individual lasers and with a desired spectral shape for the purpose of performing a photolithographic exposure according to the principles of achromatic Talbot lithography, substantially the same optical systems may be alternatively employed for combining the output beams from a number of lasers having substantially the same central wavelength so as to form a higher-intensity, uniform beam with substantially the same monochromatic spectral profile as that of the individual lasers for the purpose of performing a lithographic exposure according to the principle of displacement Talbot lithography. Such a higher-intensity beam offers the advantage of a shorter exposure time and therefore a higher wafer throughput than that obtainable using a single laser. In such embodiments, a set of, for example, 20 lasers, each having a central wavelength of, for example, 375 nm (and spectral bandwidth ˜1 nm), may be employed, which may also be obtained from the company Nichia Corporation. Since DTL does not have the same requirements as ATL with respect to the shape of the spectral profile, the drive currents of the lasers may be adjusted so that the output powers of the lasers are substantially the same. Clearly for this application, there is also no need for a spectral filter in the optical system to subsequently modify the shape of the spectral distribution of the light in the combined beam.

An illumination beam with a larger spectral bandwidth and a required shape generated from multiple lasers having a range of output central wavelengths and with such exposure systems as illustrated in the above embodiments may be alternatively employed for performing a DTL-type exposure in which the separation between the mask and wafer is varied during the exposure. Such an exposure provides certain advantages over a DTL exposure according to the prior art, in which a periodic pattern is illuminated by a substantially monochromatic beam. Specifically, it is advantageous when the intensity variation of the light-field thereby generated in a direction orthogonal to the mask deviates significantly from a periodic form. This occurs if, for example, second or higher diffraction orders are also present in the light-field between the mask and wafer, which modulate the optical interference between the zeroth and first diffraction orders. It can also be advantageous if the means for varying the separation of the mask and wafer during the exposure is not sufficiently precise, or is not accurately synchronized with the duration of the exposure process, both of which can result in inhomogeneities and/or irreproducibility in the printed pattern. This is especially exacerbated by rapid and/or strong oscillations of the intensity as a function of distance from the mask. By illuminating the mask instead with a beam having a broader spectral distribution the results obtained using a DTL-type exposure can be significantly improved. This can be understood by considering the intensity oscillation of the transmitted light-field in the direction orthogonal to the mask that is produced by an ATL exposure: the amplitude of the intensity oscillation reduces as a function of the distance from the mask such that it reaches a relatively small value at a distance much smaller than that required to obtain the stationary image according to ATL. In addition, the amplitude of higher-frequency oscillations of the intensity distribution, which are generated by second and higher diffraction orders, are reduced more quickly with increasing distance from the mask than the fundamental intensity oscillation characterized by the Talbot distance. Therefore, by performing the DTL method with an illumination beam having a broader spectral distribution generated by combining the beams from multiple laser sources having a range of wavelengths using exposure systems as illustrated in the embodiments of the present invention enables higher reproducibility and homogeneity of the printed patterns. This technique alternatively or additionally permits the precision required of the DTL displacement to be reduced in comparison with that required by the prior art for obtaining a particular reproducibility and homogeneity of the printed pattern.

These advantages are further illustrated by the following example. An amplitude mask bearing a hexagonal pattern of holes with a nearest-neighbour distance of 900 nm is illuminated by a beam having a central wavelength of 365 nm. In a first case the mask is illuminated by a monochromatic beam, and in a second case it is illuminated by a beam having a Gaussian spectrum with a FWHM width of 4.7 nm. FIG. 9 shows the dependences of the intensity of the transmitted light-field as a function of distance from the mask, in the interval 100-110 um, for these two illumination cases: “Plot 1” and “Plot 2” are for the monochromatic and Gaussian cases respectively. It can be seen that the amplitude of the intensity oscillations is reduced by a factor of about 4 in the second case. In addition the high-frequency oscillations present in the first case are absent in the second. Therefore, the DTL method performed using illumination with a Gaussian spectrum reduces the sensitivity of the printed pattern to variations in the integration distance and to the starting distance of the integration.

In other embodiments of the invention, the shape required of the spectral distribution for obtaining a stable stationary image that is substantially invariant to further increase in the distance of the photo resist-coated substrate from the mask may be determined by considering the Fourier transform of the spectral distribution. As explained previously, the stabilization of the image as a function of distance from the mask can be found through electromagnetic simulations taking into account the spectrum of the beam and details of the grating. In order to estimate the amplitude of oscillations of the intensity along the z-direction one can also use the Fourier Transform of the spectrum of light transmitted by the grating. For example, in the case of a purely monochromatic beam the spectrum can be represented by an impulse function whose Fourier Transform is constant. Therefore, for a purely monochromatic illumination the intensity oscillations continue indefinitely with constant amplitude.

The relation between the intensity oscillations along z-axis and the Fourier transform of the beam spectrum is illustrated by a further example in FIGS. 10, 11 and 12. In this example a two-dimensional grating with a hexagonal arrangement of holes with a nearest-neighbour distance of 720 nm is illuminated with light that has a square-wave spectrum. The spectrum is centred at a wavelength of 365 nm and has a width of 4 nm as illustrated in FIG. 10. FIG. 11 shows the absolute value of the Fourier transform of this spectrum and FIG. 12 shows the calculated intensity distribution along the optical axis. The intensity in that plot is calculated at a point that corresponds to the centre of one of the holes in the mask. The correspondence between the Fourier transform and the intensity oscillations is evident. In general the amplitude of intensity oscillations at a distance z can be roughly estimated by calculating the Fourier transform of the spectrum at a spatial frequency that corresponds to that z value. This correspondence is given by the following relation

$$f = z \{ \frac{1}{{p}^{2} cos ϕ ( {λ}_{0} )} - \frac{1 - cos ϕ ( {λ}_{0} )}{{λ}^{2}} \} , \qquad equ . ( 11 )$$

where f is the spatial frequency point at which the Fourier transform of the spectrum is calculated, λ₀ is the central frequency of the spectrum, p is the period of the mask pattern, and φ(λ₀) is the angle of diffraction of the first diffracted order.

Let us now illustrate in more detail how this method can be used with an example. For example let us assume that we are interested in printing a hexagonal array of holes with a nearest-neighbour distance of 720 nm and our illuminating beam has a central wavelength of 365 nm. Let us further assume that we are interested in printing this pattern at a distance of about z=100 um or above from the mask using the ATL method. From equ. (11), we calculate the spatial frequency that corresponds to this distance as f=0.175 nm⁻¹. Therefore, the Fourier transform of the spectrum should have no significant intensity for spatial frequencies of 0.175 nm⁻¹ and above. For comparison of the Fourier transform method with the criterion that we introduced in equ. (7), let us calculate the width w of the spectrum that would give us a stationary image beyond a distance of 100 um. Using equation 6 we find that a Gaussian-like spectrum with a FWHM (2w) of 5.7 nm is required to satisfy our printing needs in this example introduced above. We find that the spatial frequency that we calculated using the above equation (f=0.175 nm⁻¹) is equal to inverse of the FWHM calculated from equ. (7), i.e. f=½w. Therefore both methods give us similar results. Whereas equ. (7) works especially well for Gaussian-like smooth spectra, for more complicated spectra, for example, spectra with multiple peaks, use of the Fourier transform method may be preferred as a way to estimate the behaviour of intensity oscillations and the required stabilization distances. The Fourier transform method can be conveniently used since it does not require the performance of an electromagnetic simulation. Many available software tools, for example Matlab software developed by MathWorks has Fourier transform functions that can readily perform the calculation for a given spectrum.

The estimates given by equ. (7) based on the width of the spectrum or the Fourier transform of the spectrum explained above should be used as general guides. The amplitude of oscillations also generally depends on the details of the mask pattern, such as the feature size, and on the phase shifting and/or attenuating properties of the features. In addition, the requirements of the application and the characteristics of the photo resist process influence how much the oscillation of intensity with increasing distance from the mask can be tolerated. Therefore, depending on requirements of the process a suitable electromagnetic calculation, taking into account the details of the grating and the application may be used to determine the oscillation amplitude at a particular distance along with image contrast. The results of such optical calculations may be used in calculating the expected pattern in photo resist using simulation tools designed for such photo resists.

The teachings of the present invention may be applied to the design of an exposure system whilst also taking into consideration other requirements of the lithographic application, such as an acceptable range of separations between mask and substrate and a desired exposure time. For such a design, the specifications of the exposure system are first defined including, for example, the range of periodic pattern types and periods to be printed, the allowable separations between mask and photoresist-coated substrate, the largest pattern area to be printed, the sensitivity of the photoresist and the desired exposure time. The acceptable range of separations between mask and wafer may be influenced by the necessity to avoid damage caused by contact between mask and wafer, and to provide a certain tolerance to particulate contamination or wafer non-flatness. Based on these system specifications, the illumination conditions required at the mask, specifically, the area of the exposure field, A, the intensity of illumination, φ, the range of angles of the beam's rays in orthogonal planes (i.e. degree of de-collimation), θ, and bandwidth (preferably the FWHM value) of the spectral distribution, w, may then be determined. The intensity of illumination required depends on the sensitivity of the photo resist, the transmission of the photo mask and the targeted exposure time. The degree of collimation required depends on the targeted resolution of the printed pattern, and may be determined using equ. (8). The spectral bandwidth required of the illumination beam depends on the distance from the mask at which the stationary image should be formed, which may be estimated using equ. (7).

As related in the above embodiments, suitable laser sources for implementing the invention are a set of laser diodes having a range of output wavelengths. The output characteristics of such lasers may be defined in terms of the available range of wavelengths, λₘᵢₙ to λₘₐₓ, the maximum power available from each laser for the wavelength concerned, P_{λ}, the dependence of the output power of each laser on its drive current for the wavelength concerned, P_{λ}=f_{λ}(I), the spectral linewidth of the beam from each laser, Δλ, and the beam's étendue, s, which may be defined as the product of the beam's cross-section at a plane in the divergent beam and the solid angle of the rays propagating through each point of the cross-section in that plane (both Δλ and s may be assumed to be substantially the same for the different lasers). Based on this and an estimate of the transmission efficiency, ε, of the optical system between the lasers and the mask, it is then possible to select the number of lasers, N, their peak wavelengths, λ₁, λ₂, . . . λ_{N}, and the drive currents, I₁, I₂, . . . I_{N}, that are required for generating the above-determined spectral distribution and beam intensity for achieving the targeted specifications. According to a fundamental optical principle, the étendue of light propagating through an optical system is either conserved or may increase: it cannot decrease (assuming no light is lost by spatial filtering or equivalent). Consequently, the étendue of the beam, S, illuminating the mask cannot be less than the sum of the étendues of the beams from the different laser sources, that is

S≧Ns equ. (12)

and therefore

Aθ²≧Ns equ. (13)

If this condition is not satisfied, then the beams from the N laser sources cannot be combined (at least not without spatial filtering the light and unacceptable loss of laser power) to produce a beam of cross-sectional area, A, and degree of de-collimation, θ. For such a case, a compromise would be needed. For example, the light in the combined beam may be spatially filtered to reduce its étendue, thereby reducing the left-hand side of the above expression; or alternatively, the number of lasers may be reduced. If the latter option is selected the impact on the spectral width has to be considered: for example, a reduced spectral width may necessitate the use of a larger separation between the mask and wafer, and therefore require an even smaller beam de-collimation. And in both cases the intensity of the illumination beam would be reduced, with detrimental effects on the exposure time and system throughput.

Furthermore, depending on the means employed for combining the beams from the N laser sources, the étendue of the light in the combined beam may be substantially larger than the Ns given on the right-hand side of equ. (13). Therefore, whilst a violation of the condition would definitely demand a reconsideration of the system specifications, a non-violation does not ensure that the illumination requirements, in terms of beam-size and de-collimation angle at the mask, are fulfilled. Consequently, equ. (13) represents a minimum requirement, which may need to be increased depending on the system design. In certain cases practical and design-related constraints may make it impossible to combine the beams (at least not without unacceptable loss of power) so that the resulting beam has an étendue of Ns.

The above-described sequence of procedural steps that may be employed for designing a lithographic exposure system based on the teaching of the present invention is illustrated in the flowchart depicted in FIG. 13. It should be understood that other design strategies may be alternatively employed.

In the case of the first embodiment detailed above, the number of laser sources employed is 20, the emitting cross-section of each LD is ˜10 μm², and the divergence of the output beam from each LD in orthogonal planes is typically ˜15°×30° (FWHM values); and so, the total étendue of the output beams, i.e. the right-hand side of equ. (13), is determined to be ˜0.3 cm² mR². The area of the beam illuminating the mask in the first embodiment, on the other hand, is ˜225 cm² (ignoring any truncation by the lens aperture) and the degree of collimation in the beam ˜1.4 mR in each plane; and so, the étendue of the beam illuminating the mask, i.e. the left-hand side of equ. (13), is ˜440 cm² mR². The condition described by equ. (13) is therefore easily respected, confirming that it may be possible to design an optical system for achieving the requirements. The right-hand side of equ. (13) may also be calculated at an intermediate location in the optical system of the first embodiment to verify that the total étendue does not increase through a part of the system. For example, it may be calculated at the output of fibre 6. Here the area of the emitting surface is ˜0.33 mm² and the divergence angle of the output beam is ˜10° in orthogonal planes; and so, the beam's étendue at the end of the fibre 6 is ˜100 cm² mR². This is much smaller than that calculated above for the beam illuminating the mask, confirming that it may be possible to design an optical system for transforming the output beam of the fibre 6 into one with the properties required for illuminating the mask.

While the embodiments described above may be considered as preferred embodiments of the invention, it should, of course, be understood that various modifications and changes in form or detail could readily be made without departing from the spirit of the invention. It is therefore intended that the invention should not be limited to the exact forms described and illustrated, but should be constructed to cover all modifications that may fall within the scope of the appended claims.

1-20. (canceled)

21. A method for printing a desired periodic pattern of features into a photosensitive layer, which method comprises:
a) providing a mask bearing a mask pattern with a period;
b) providing a substrate bearing the photosensitive layer;
c) arranging the substrate substantially parallel to and with a separation from the mask;
d) providing a plurality of laser diodes having a plurality of different peak emission wavelengths, wherein at least one of the peak emission wavelengths may be varied by adjusting a temperature and/or a drive current of at least one of said laser diodes such that said laser diodes together emit light over a range of wavelengths;
e) forming from the light a beam for illuminating the mask with a spectral distribution of exposure dose over the range of wavelengths and having a degree of collimation;
f) illuminating the mask with the beam, while adjusting at least one of the temperature or the drive current of at least one of said laser diodes so as to expose the mask with the spectral distribution of dose, such that the light of each wavelength transmitted by the mask pattern forms a range of transversal intensity distributions between Talbot planes and exposes the photosensitive layer to an image component, whereby a time-integrated superposition of the components prints the desired periodic pattern;
wherein the separation and spectral distribution are configured in relation to the period so that the superposition of the components is substantially equivalent to an average of the range of transversal intensity distributions formed by light at any one of the wavelengths, and
wherein the degree of collimation is configured in relation to the separation so that the features of the printed pattern are resolved.

22. The method according to claim 21, which comprises forming the illumination beam with a spectral distribution of intensity that corresponds substantially to a spectral distribution of exposure dose, and illuminating the mask with light of each wavelength for an exposure time that is substantially equal for all wavelengths.

23. The method according to claim 21, which comprises forming the illumination beam with light whose intensity at each of the peak wavelengths is substantially equal, and illuminating the mask with light of each peak wavelength for an exposure time whose dependence on wavelength corresponds substantially to the spectral distribution.

24. The method according to claim 21, wherein the spectral distribution corresponds substantially to a profile selected from the group consisting of a truncated Gaussian, a truncated cosine, a triangular and a trapezoidal profile.

25. The method according to claim 21, wherein light of the central wavelength of the range transmitted by the mask pattern forms Talbot planes that are separated by a Talbot distance and the spectral distribution has a full-width at half-maximum such that illumination of the mask by a monochromatic beam, the wavelength of which is varied over the full-width at half-maximum of the distribution, would cause the transversal intensity distribution illuminating the photosensitive layer to longitudinally displace by a distance that corresponds substantially to the Talbot distance.

26. The method according to claim 21, which comprises illuminating the mask by the light from the plurality of lasers simultaneously.

27. The method according to claim 21, which comprises illuminating the mask by the light from the plurality of lasers sequentially.

28. The method according to claim 21, wherein the illumination beam has a spectral distribution of intensity that is substantially uniform across the beam.

29. The method according to claim 21, which comprises causing the light of the different peak wavelengths to be spatially separated in the illuminated beam and scanning the beam across the mask during the illumination.

30. The method according to claim 21, which comprises forming the illumination beam to have an intensity that is substantially uniform across the beam.

31. The method according to claim 21, wherein the spectral distribution of exposure dose has a substantially smooth profile.

32. An apparatus for printing a desired periodic pattern of features into a photosensitive layer, the apparatus comprising:
a) a mask bearing a mask pattern with a period;
b) a substrate bearing the photosensitive layer;
c) a device configured to arrange the substrate substantially parallel to the mask and with a separation;
d) a plurality of laser diodes having a plurality of different peak emission wavelengths;
e) a device for varying the peak wavelength of at least one of said lasers by adjusting a temperature and/or a drive current of at least one of said lasers such that said lasers together emit light over a range of wavelengths;
f) a device for forming from the emitted light an illumination beam having the range of wavelengths for exposing the photosensitive layer to a pre-determined spectral distribution of exposure dose and having a degree of collimation;
g) a device for illuminating the mask with the beam such that the light of each wavelength transmitted by the mask pattern forms a range of transversal intensity distributions between Talbot planes and exposes the photosensitive layer to an image component, whereupon a time-integrated superposition of the components prints the desired pattern;
wherein the separation and the spectral distribution are arranged in relation to the period so that the superposition of the components is substantially equivalent to an average of the range of transversal intensity distributions formed by light at any one of the wavelengths, and the degree of collimation is configured in relation to the separation so that the features of the desired periodic pattern are resolved.

33. The apparatus according to claim 32, wherein said device for forming the illumination beam includes an optical fiber for mixing the light of the different wavelengths to form the illumination beam with a substantially uniform spectral distribution.

34. The apparatus according to claim 32, wherein said device for forming the illumination beam includes at least one array of micro-lenses for directing the light of the different wavelengths and to form the illumination beam with a substantially uniform intensity in at least one direction.

35. The apparatus according to claim 32, wherein said device for forming the illumination beam includes a spectral filter having a spectral transmission or reflection profile corresponding substantially to the spectral distribution of exposure dose.

36. The apparatus according to claim 32, wherein said lasers are configured to emit light at peak wavelengths that are substantially equally spaced over a wavelength range.

37. The apparatus according to claim 32, which further comprises a device for pulsing or modulating the intensity of the beam from each laser with a frequency and a duty cycle such that the dependence of the duty cycle on the peak wavelength of the respective laser corresponds to the spectral distribution of exposure dose.
